(19) United States
(12) Patent Application Publication
(10) Pub. No.: US 2024/0105687 A1
(43) Pub. Date: Mar. 28, 2024

(54) PACKAGE COMPRISING A FLEXIBLE SUBSTRATE

(71) Applicant: QUALCOMM Incorporated, San Diego, CA (US)

(72) Inventors: Joan Rey Villarba BUOT, Escondido, CA (US); Hong Bok WE, San Diego, CA (US); Zhijie WANG, San Diego, CA (US); Aniket PATIL, San Diego, CA (US)

(21) Appl. No.: 17/951,702

(22) Filed: Sep. 23, 2022

(51) Int. Cl. H01L 25/10; H01L 23/31; H01L 23/498; H01L 23/538

(52) U.S. Cl. CPC H01L 25/105; H01L 23/3128; H01L 23/49816; H01L 23/5387

(57) ABSTRACT

A package comprising a substrate, a first integrated device coupled to a first surface of the substrate, and a second integrated device coupled to the first surface of the substrate; wherein a back side of the second integrated device is coupled to a back side of the first integrated device through an adhesive. The substrate includes at least one dielectric layer and a plurality of interconnects. The substrate includes a flexible portion that is configured to be bend such that the back side of the first integrated device faces the back side of the second integrated device in the package.

### FIELD

Various features relate to packages with a substrate.

### BACKGROUND

A package may include a substrate and integrated devices. These components are coupled together to provide a package that may perform various functions. The performance of a package and its components may depend on the quality of the joints between various components of the package. There is an ongoing need to provide packages that include robust and reliable joints between components. Moreover, there is an ongoing need to include a package that includes a more compact form factor so that the package may be implemented in smaller devices.

### SUMMARY

Various features relate to packages with a substrate.

One example provides a package comprising a substrate, a first integrated device coupled to a first surface of the substrate, and a second integrated device coupled to the first surface of the substrate, where a back side of the second integrated device is coupled to a back side of the first integrated device through an adhesive. The substrate includes at least one dielectric layer and a plurality of interconnects.

Another example provides a device comprising a substrate, a first integrated device coupled to a first surface of the substrate, and a second integrated device coupled to the first surface of the substrate, where a back side of the second integrated device is coupled to a back side of the first integrated device through an adhesive. The substrate includes at least one dielectric layer and a plurality of interconnects.

Another example provides a method for fabricating a package. The method provides a substrate comprising at least one dielectric layer, and a plurality of interconnects. The method couples a first integrated device to a first surface of the substrate. The method couples a second integrated device to the first surface of the substrate. The method bends the substrate and couples a back side of the second integrated device to a back side of the first integrated device through an adhesive.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile cross sectional view of an exemplary package that includes a flexible substrate and integrated devices.

FIG. 2 illustrates a profile cross sectional view of an exemplary package that includes a flexible substrate and integrated devices.

FIG. 3 illustrates a profile cross sectional view of an exemplary package that includes a flexible substrate and integrated devices.

FIG. 4 illustrates a profile cross sectional view of an exemplary package that includes a flexible substrate and integrated devices.

FIG. 5 illustrates a profile cross sectional view of an exemplary package that includes a flexible substrate and integrated devices.

FIG. 6 illustrates a profile cross sectional view of an exemplary package that includes a flexible substrate and integrated devices.

FIG. 7 illustrates a profile cross sectional view of an exemplary package that includes a flexible substrate and integrated devices.

FIG. 8 illustrates a profile cross sectional view of an exemplary package that includes a flexible substrate and integrated devices.

FIG. 9 illustrates a profile cross sectional view of an exemplary package that includes a flexible substrate and integrated devices.

FIG. 10 illustrates a profile cross sectional view of an exemplary package that includes a flexible substrate and integrated devices.

FIG. 11 illustrates a profile cross sectional view of an exemplary package that includes a flexible substrate and integrated devices.

FIG. 12 illustrates a plan view of an exemplary package that includes a flexible substrate and integrated devices.

FIGS. 13A-13B illustrate an exemplary sequence for fabricating a package that includes a flexible substrate and integrated devices.

FIG. 14 illustrates an exemplary flow diagram of a method for fabricating a package that includes a flexible substrate and integrated devices.

FIG. 15 illustrates an exemplary sequence for fabricating a flexible substrate.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate, a first integrated device coupled to a first surface of the substrate, and a second integrated device coupled to the first surface of the substrate; wherein a back side of the second integrated device is coupled to a back side of the first integrated device through an adhesive. The substrate includes at least one dielectric layer and a plurality of interconnects. The substrate includes a flexible portion that is configured to bend such that the back side of the first integrated device faces the back side of the second integrated device in the package. The package may include a plurality of solder interconnects. The substrate comprises a first portion and a second portion. The first portion faces the second portion when the substrate is bent. The plurality of solder interconnects are coupled to the first portion and the second portion. The use of a flexible substrate helps provide a package with a more compact form factor, which allows the package to be implemented in smaller devices. Moreover, the use of solder interconnects to couple to different portions of the flexible substrate helps provide a more direct electrical path between integrated devices coupled to different portions of the flexible substrate, which can lead to improved performances for the integrated device and the package.

### Exemplary Package Comprising an Integrated Device and a Flexible Substrate

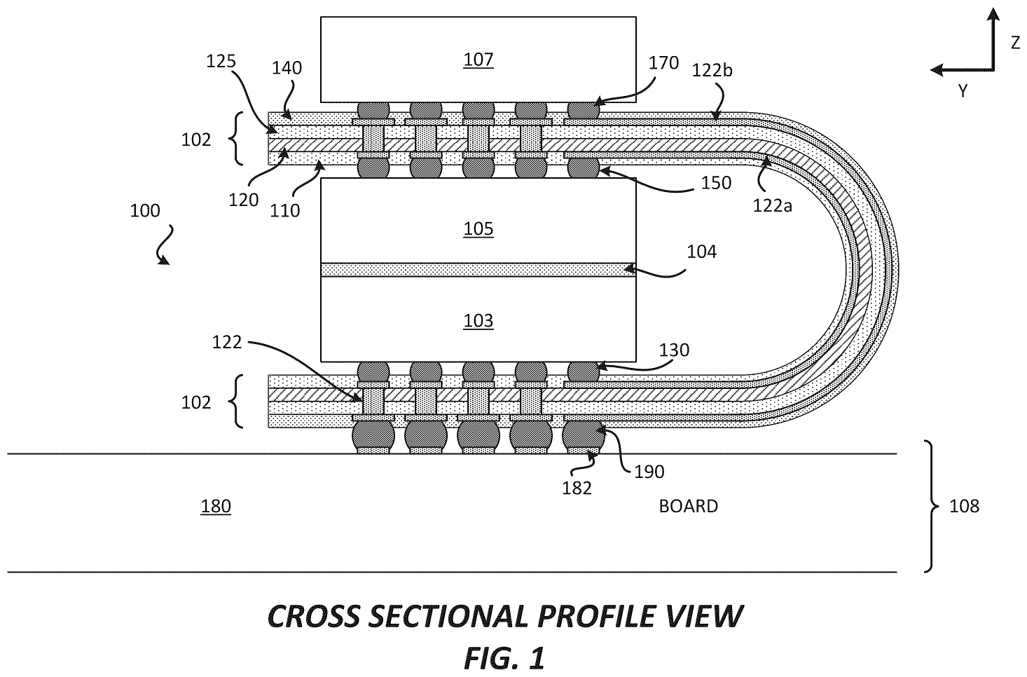

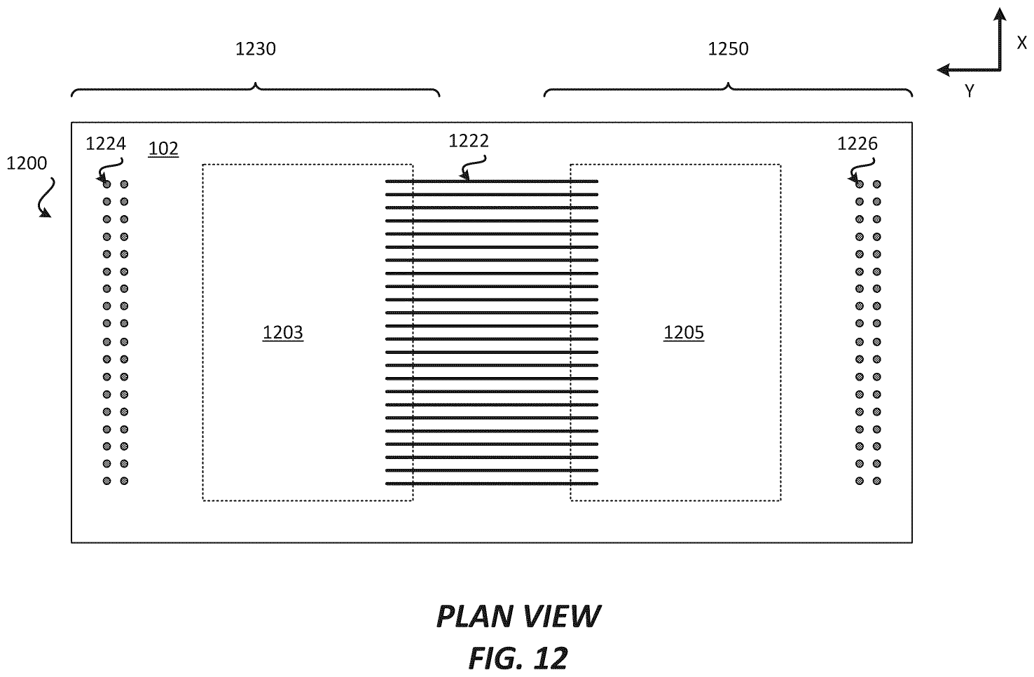

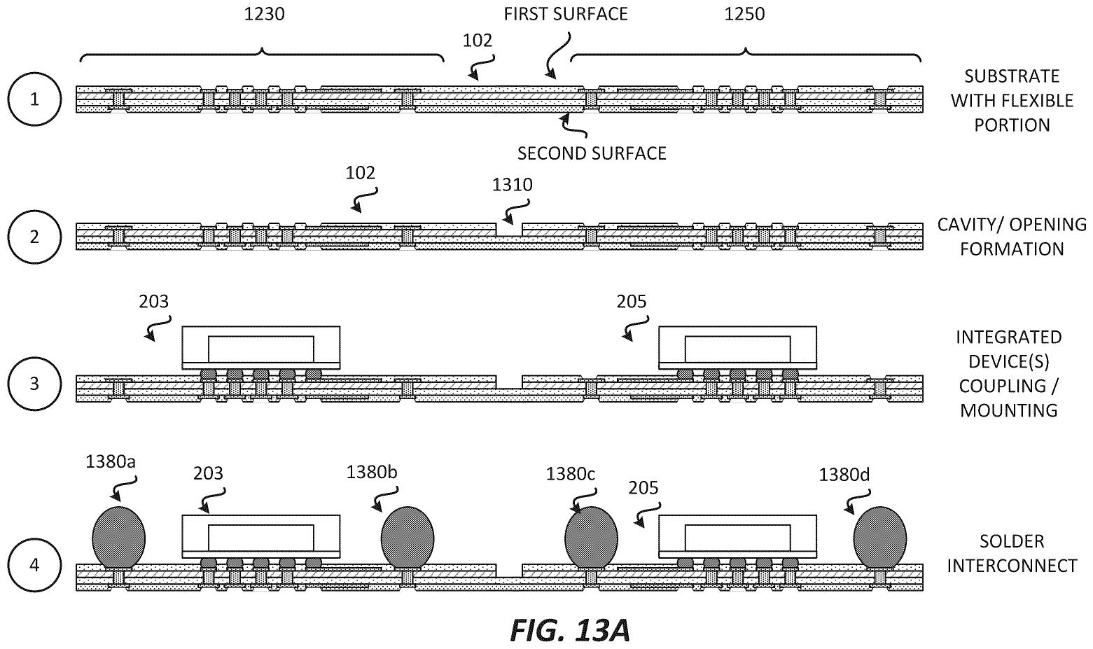

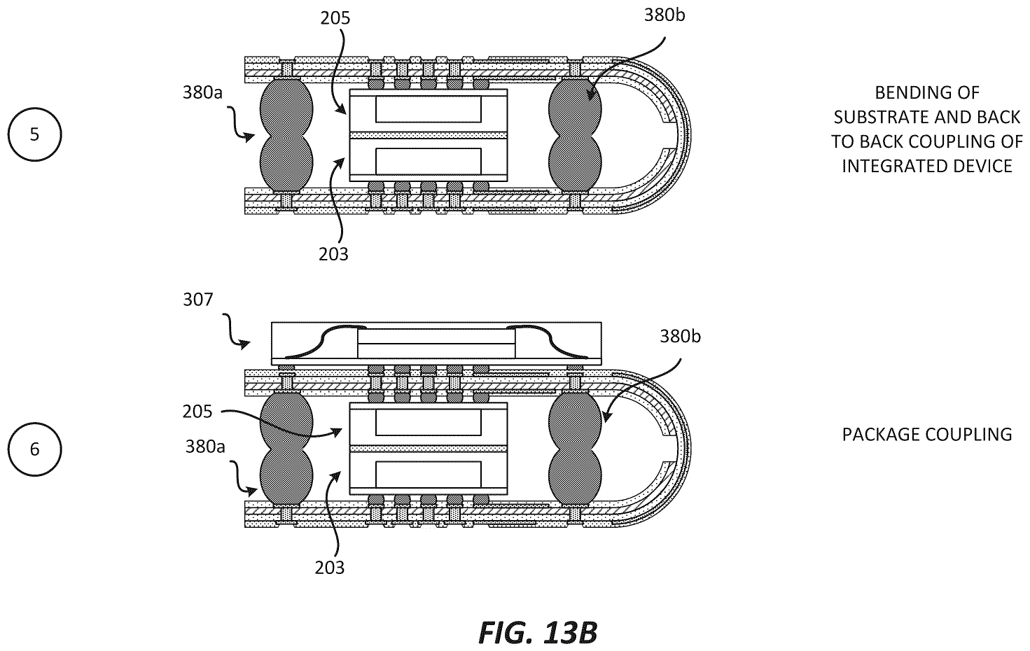

FIG. 1 illustrates a profile cross sectional view of a package 100 that includes a flexible substrate. The package 100 includes a substrate 102, an integrated device 103, an integrated device 105 and an integrated device 107. The integrated device 103 may be a first integrated device. The integrated device 105 may be a second integrated device. The integrated device 107 may be a third integrated device. The substrate 102 includes a flexible substrate. The substrate 102 includes a flexible portion that can be configured to bend by at least 180 degrees. The package 100 is coupled to a board 108 (e.g., printed circuit board) through a plurality of solder interconnects 190. The board 108 includes at least one board dielectric layer 180 and a plurality of board interconnects 182. The package 100 is coupled to the plurality of board interconnects 182 of the board 108 (e.g., printed circuit board) through a plurality of solder interconnects 190. The substrate 102 includes a first surface and a second surface. The substrate 102 may be coupled to the board 108 such that a first portion of the second surface of the substrate 102 faces the board 108. For example, the substrate 102 may be coupled to the board 108 such that a first portion of the solder resist layer 140 from the second surface of the substrate 102 faces the board 108. Examples of what a first portion and a second portion of a substrate may be are illustrated and described below in at least FIGS. 12 and 13A.

The substrate 102 includes a first surface and a second surface. The substrate 102 includes a dielectric layer 110, a dielectric layer 120, a dielectric layer 125, a solder resist layer 140 and a plurality of interconnects 122 (e.g., plurality of substrate interconnects). The dielectric layer 120 may include a stiffener dielectric layer. The dielectric layer 120 (e.g., stiffener dielectric layer) may be optional. The dielectric layer 110 and/or the dielectric layer 125 may include prepreg. The plurality of interconnects 122 may include an interconnect 122a and an interconnect 122b. The interconnect 122a may include an interconnect located on a first metal layer (e.g., M1) of the substrate 102. The interconnect 122a may be located at least in the flexible portion of the substrate 102. The interconnect 122b may include an interconnect located on a second metal layer (e.g., M2) of the substrate 102. The interconnect 122b may be located at least in the flexible portion of the substrate 102. In some implementations, the first surface of the substrate 102 includes the dielectric layer 110. In some implementations, the second surface of the substrate 102 includes the solder resist layer 140.

FIG. 1 illustrates that the substrate 102 is bent such that one portion of the dielectric layer 110 faces another portion of the dielectric layer 110. However, in some implementations, the substrate 102 may be bent such that one portion of the solder resist layer 140 faces the another portion of the solder resist layer 140. Thus, the substrate 102 may be bent in many different ways and it not limited by what is shown in the figures. In some implementations, when the substrate 102 is bent such that one portion of the solder resist layer 140 faces the another portion of the solder resist layer 140, the first surface of the substrate 102 may include the solder resist layer 140 and the second surface of the substrate 102 may include the dielectric layer. In some implementations, a first surface of the substrate 102 may be an inner surface of the substrate 102, and a second surface of the substrate 102 may be an outer surface of the substrate 102.

The integrated device 103 includes a front side (e.g., first back side) and back side (e.g., first back side). The integrated device 103 is coupled to a first portion of the first surface of the substrate 102 through a plurality of solder interconnects 130 such that the front side of the integrated device 103 faces the first portion of the first surface of the substrate 102. For example, the integrated device 103 is coupled to a first plurality of interconnects from the plurality of interconnects 122 of the substrate 102 through a plurality of solder interconnects 130 such that the front side of the integrated device 103 faces the first portion of the first surface of the substrate 102. The integrated device 103 may include a chiplet.

The integrated device 105 includes a front side (e.g., second back side) and back side (e.g., second back side). The integrated device 105 is coupled to a second portion of the first surface of the substrate 102 through a plurality of solder interconnects 150 such that the front side of the integrated device 105 faces the second portion of the first surface of the substrate 102. For example, the integrated device 105 is coupled to a second plurality of interconnects from the plurality of interconnects 122 of the substrate 102 through a plurality of solder interconnects 150 such that the front side of the integrated device 105 faces the second portion of the first surface of the substrate 102. The integrated device 105 may include a chiplet.

The integrated device 103 may be coupled to the integrated device 105 through an adhesive 104. For example, the back side of the integrated device 103 may be coupled to the back side of the integrated device 105 through the adhesive 104. Thus, the back side of the integrated device 103 may face the back side of the integrated device 105, and vice versa.

The integrated device 107 includes a front side (e.g., third back side) and back side (e.g., third back side). The integrated device 107 is coupled to a second portion of the second surface of the substrate 102 through a plurality of solder interconnects 170 such that the front side of the integrated device 107 faces the second portion of the second surface of the substrate 102. For example, the integrated device 107 is coupled to a third plurality of interconnects from the plurality of interconnects 122 of the substrate 102 through a plurality of solder interconnects 170 such that the front side of the integrated device 107 faces the second portion of the second surface of the substrate 102.

The integrated device 103 is configured to be electrically coupled to the integrated device 105 and/or the integrated device 107 through the substrate 102. For example, an electrical path between the integrated device 103 and the integrated device 105 may include at least one solder interconnect from the plurality of solder interconnects 130, at least one interconnect from the plurality of interconnects 122 and at least one solder interconnect from the plurality of solder interconnects 150. An electrical path between the integrated device 103 and the integrated device 107 may include at least one solder interconnect from the plurality of solder interconnects 130, at least one interconnect from the plurality of interconnects 122 and at least one solder interconnect from the plurality of solder interconnects 170. An electrical path between the integrated device 105 and the integrated device 107 may include at least one solder interconnect from the plurality of solder interconnects 150, at least one interconnect from the plurality of interconnects 122 and at least one solder interconnect from the plurality of solder interconnects 170.

FIG. 1 illustrates an example of a package that is more compact and takes up less real estate in the lateral directions. By bending and/or folding the substrate 102 by at least 180, the package 100 takes up less lateral space at the expense of the package being slightly thicker, which may allow the package to fit in a space and/or device that has little lateral space, but sufficient vertical space.

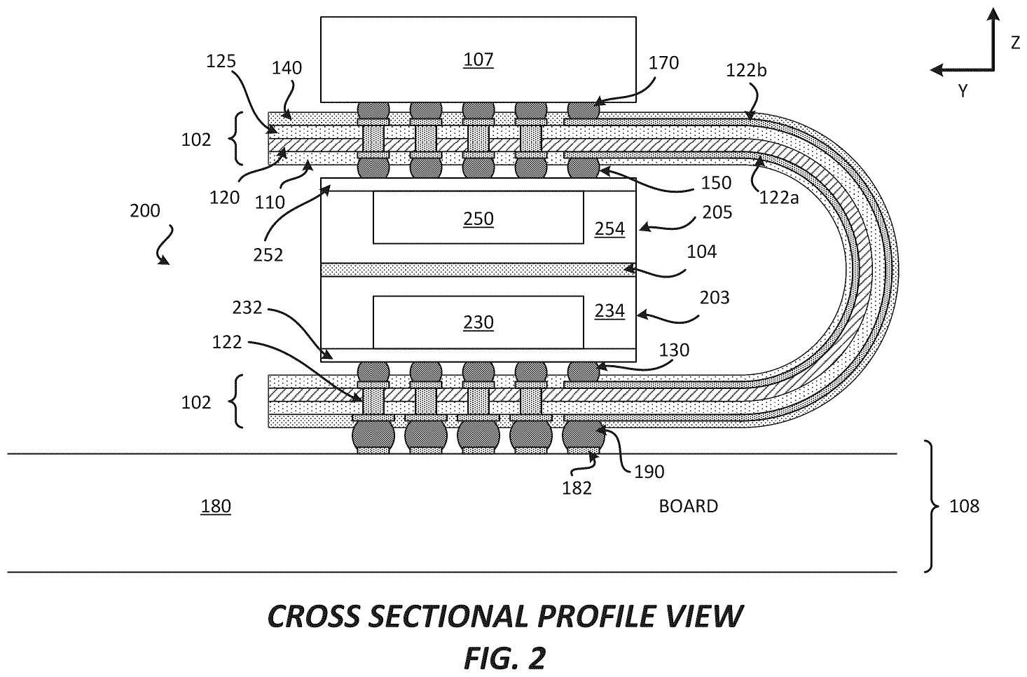

FIG. 2 illustrates a configuration of a package 200 that includes a flexible substrate. The package 200 is similar to the package 100, and thus includes the same or similar components that are arranged in a similar manner as the package 100.

The package 200 includes the substrate 102, an integrated device 203, an integrated device 205 and the integrated device 107. The integrated device 203 may be a first integrated device. The integrated device 205 may be a second integrated device. The integrated device 107 may be a third integrated device. The integrated device 203 includes a metallization portion 232, a die 230 (e.g., semiconductor die) and an encapsulation layer 234. The die 230 is coupled to the metallization portion 232. The encapsulation layer 234 is coupled to the die 230 and the metallization portion 232. The encapsulation layer 234 encapsulates the die 230. The metallization portion 232 may include at least one dielectric layer and a plurality of interconnects. The metallization portion 232 may be a redistribution portion that includes at least one dielectric layer and a plurality of redistribution interconnects.

The integrated device 205 includes a metallization portion 252, a die 250 (e.g., semiconductor die) and an encapsulation layer 254. The die 250 is coupled to the metallization portion 252. The encapsulation layer 254 is coupled to the die 250 and the metallization portion 252. The encapsulation layer 254 encapsulates the die 250. The metallization portion 252 may include at least one dielectric layer and a plurality of interconnects. The metallization portion 252 may be a redistribution portion that includes at least one dielectric layer and a plurality of redistribution interconnects.

The integrated device 203 includes a front side (e.g., first back side) and back side (e.g., first back side). The front side of the integrated device 203 may include the metallization portion 232 and the back side of the integrated device 203 may include the encapsulation layer 234. The integrated device 203 is coupled to a first portion of the first surface of the substrate 102 through a plurality of solder interconnects 130 such that the front side of the integrated device 203 faces the first portion of the first surface of the substrate 102. For example, the integrated device 203 is coupled to a first plurality of interconnects from the plurality of interconnects 122 of the substrate 102 through a plurality of solder interconnects 130 such that the front side of the integrated device 203 faces the first portion of the first surface of the substrate 102.

The integrated device 205 includes a front side (e.g., second back side) and back side (e.g., second back side). The front side of the integrated device 205 may include the metallization portion 252 and the back side of the integrated device 205 may include the encapsulation layer 254. The integrated device 205 is coupled to a second portion of the first surface of the substrate 102 through a plurality of solder interconnects 150 such that the front side of the integrated device 205 faces the second portion of the first surface of the substrate 102. For example, the integrated device 205 is coupled to a second plurality of interconnects from the plurality of interconnects 122 of the substrate 102 through a plurality of solder interconnects 150 such that the front side of the integrated device 205 faces the second portion of the first surface of the substrate 102.

The integrated device 203 may be coupled to the integrated device 205 through an adhesive 104. For example, the back side of the integrated device 203 may be coupled to the back side of the integrated device 205 through the adhesive 104. Thus, the encapsulation layer 234 of the integrated device 203 may be coupled to the encapsulation layer 254 of the integrated device 205 through the adhesive 104. The back side of the integrated device 203 may face the back side of the integrated device 205, and vice versa.

The integrated device 203 is configured to be electrically coupled to the integrated device 205 and/or the integrated device 107 through the substrate 102. For example, an electrical path between the integrated device 203 and the integrated device 205 may include at least one solder interconnect from the plurality of solder interconnects 130, at least one interconnect from the plurality of interconnects 122 and at least one solder interconnect from the plurality of solder interconnects 150. An electrical path between the integrated device 203 and the integrated device 107 may include at least one solder interconnect from the plurality of solder interconnects 130, at least one interconnect from the plurality of interconnects 122 and at least one solder interconnect from the plurality of solder interconnects 170. An electrical path between the integrated device 205 and the integrated device 107 may include at least one solder interconnect from the plurality of solder interconnects 150, at least one interconnect from the plurality of interconnects 122 and at least one solder interconnect from the plurality of solder interconnects 170.

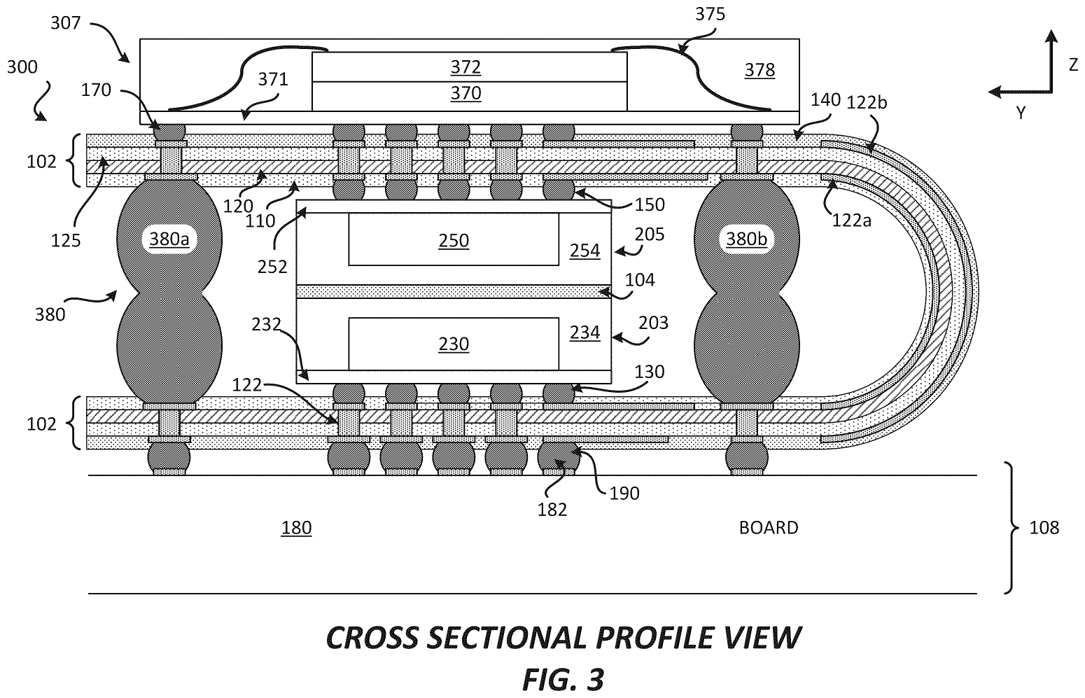

FIG. 3 illustrates a configuration of a package 300 that includes a flexible substrate. The package 300 is similar to the package 100 and the package 200, and thus includes the same or similar components that are arranged in a similar manner as the package 100 and the package 200.

The package 300 includes the substrate 102, an integrated device 203, an integrated device 205, a package 307 and a plurality of solder interconnects 380. The package 307 may include a package substrate 371, an integrated device 370, an integrated device 372, a plurality of wire bonds 375 and an encapsulation layer 378. The package substrate 371 may include at least one dielectric layer and a plurality of interconnects (not shown). The integrated device 203 and the integrated device 205 may be coupled to the substrate 102 in a similar manner as described in FIG. 2.

The package 307 includes a front side (e.g., third front side) and back side (e.g., third back side). The front side of the package 307 may include a package substrate 371, and the back side of the package 307 may include the encapsulation layer 378. The package 307 is coupled to a second portion of the second surface of the substrate 102 through a plurality of solder interconnects 170 such that the front side of the package 307 faces the second portion of the second surface of the substrate 102. For example, the package 307 is coupled to a third plurality of interconnects from the plurality of interconnects 122 of the substrate 102 through a plurality of solder interconnects 170 such that the front side of the package 307 faces the second portion of the second surface of the substrate 102.

The plurality of solder interconnects 380 may include a first plurality of solder interconnects 380a and a second plurality of solder interconnects 380b. The plurality of solder interconnects 380 is coupled to at least two different portions of the first surface of the substrate 102, where the two different portions of the first surface of the substrate 102 face each other. For example, the first plurality of solder interconnects 380a may be coupled to a first particular portion of the first surface of the substrate 102 and to a second particular portion of the first surface of the substrate 102, where the first particular portion of the first surface of the substrate 102 faces the second particular portion of the first surface of the substrate 102. The second plurality of solder interconnects 380b may be coupled to a third particular portion of the first surface of the substrate 102 and to a fourth particular portion of the first surface of the substrate 102, where the third particular portion of the first surface of the substrate 102 faces the fourth particular portion of the first surface of the substrate 102. The second plurality of solder interconnects 380a may be located between the integrated device 203 and the flexible portion, folded portion and/or bent portion of the substrate 102. The second plurality of solder interconnects 380a may be located between the integrated device 205 and the flexible portion, folded portion and/or bent portion of the substrate 102.

The integrated device 203 is configured to be electrically coupled to the integrated device 205 and/or the package 307 through the substrate 102. For example, an electrical path between the integrated device 203 and the integrated device 205 may include at least one solder interconnect from the plurality of solder interconnects 130, at least one interconnect from the plurality of interconnects 122 and at least one solder interconnect from the plurality of solder interconnects 150. An electrical path between the integrated device 203 and the integrated device 205 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 150.

An electrical path between the integrated device 203 and the package 307 may include at least one solder interconnect from the plurality of solder interconnects 130, at least one interconnect from the plurality of interconnects 122 and at least one solder interconnect from the plurality of solder interconnects 170. An electrical path between the integrated device 203 and the package 307 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 170.

An electrical path between the integrated device 205 and the package 307 may include at least one solder interconnect from the plurality of solder interconnects 150, at least one interconnect from the plurality of interconnects 122 and at least one solder interconnect from the plurality of solder interconnects 170.

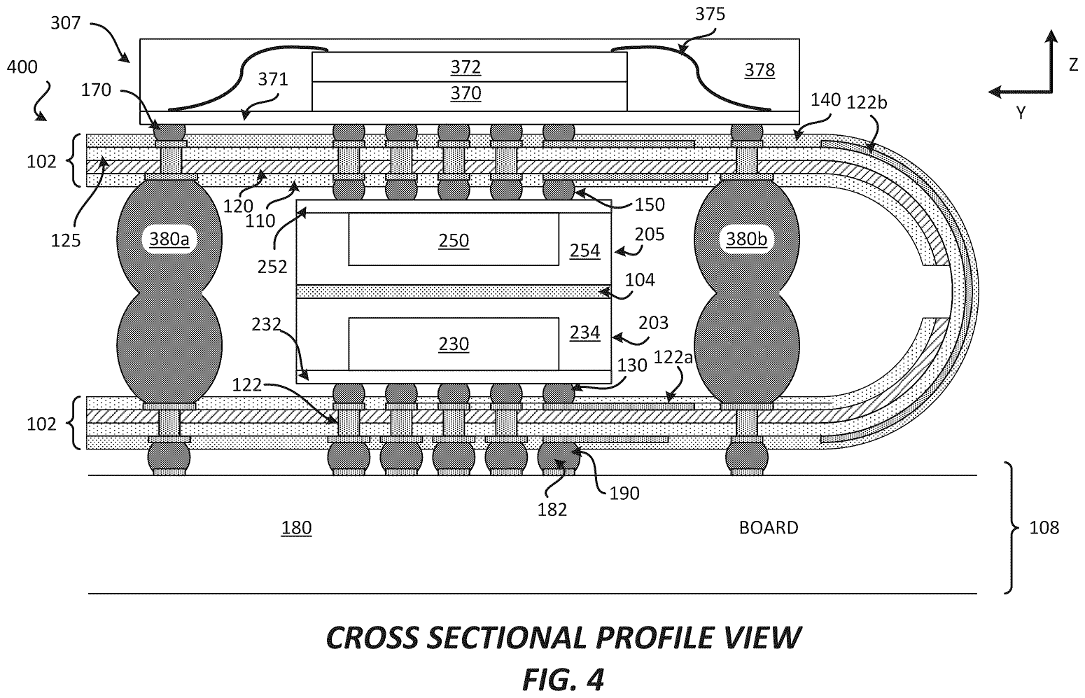

FIG. 4 illustrates a configuration of a package 400 that includes a flexible substrate. The package 400 is similar to the package 100, the package 200 and/or the package 300, and thus includes the same or similar components that are arranged in a similar manner as the package 100, the package 200 and/or the package 300. The package 400 includes the substrate 102, an integrated device 203, an integrated device 205, the package 307 and a plurality of solder interconnects 380. FIG. 4 illustrates that a portion of the substrate 102 has been removed to help with the bending of the flexible portion of the substrate 102. For example, portions of the dielectric layer 110 and/or the dielectric layer 120 may have been removed in the flexible portion of the substrate 102.

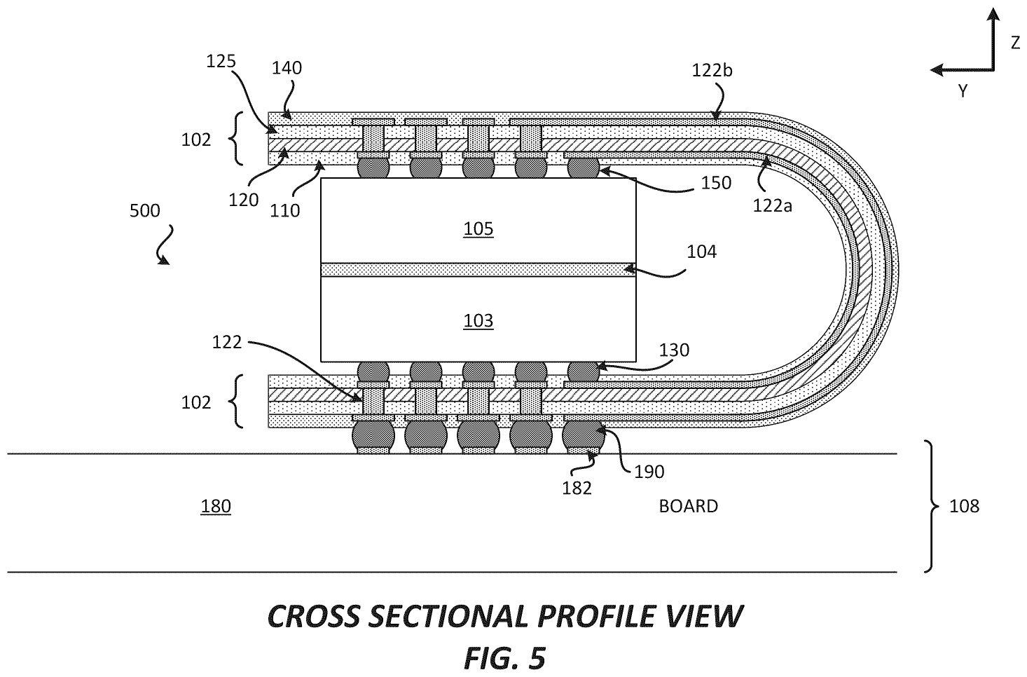

FIG. 5 illustrates the package 500 that includes a flexible substrate. The package 500 is similar to the package 100 of FIG. 1, and thus includes the same or similar components that are arranged in a similar manner as the package 100 of FIG. 1. However, the package 500 in FIG. 5 does not include the integrated device 107.

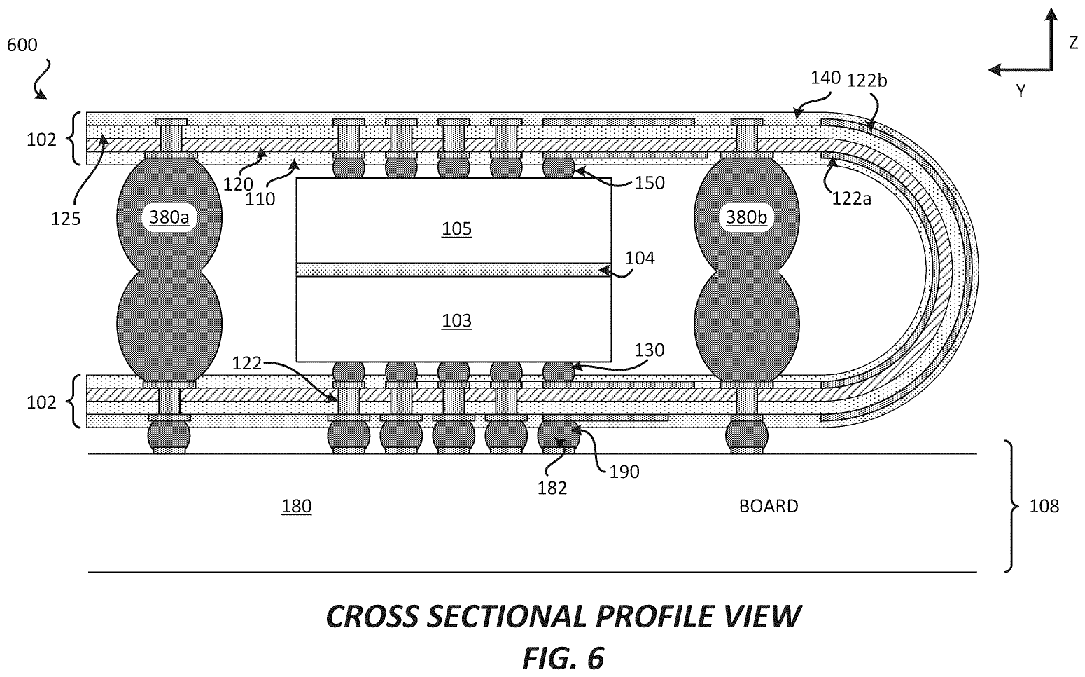

FIG. 6 illustrates the package 600 that includes a flexible substrate. The package 600 is similar to the package 100, the package 300 and the package 500, and thus includes the same or similar components that are arranged in a similar manner as the package 100, the package 300 and/or the package 500.

The package 600 includes the substrate 102, the integrated device 103, the integrated device 105 and a plurality of solder interconnects 380. The integrated device 103 is configured to be electrically coupled to the integrated device 105 through the substrate 102. For example, an electrical path between the integrated device 103 and the integrated device 105 may include at least one solder interconnect from the plurality of solder interconnects 130, at least one interconnect from the plurality of interconnects 122 and at least one solder interconnect from the plurality of solder interconnects 150. An electrical path between the integrated device 103 and the integrated device 105 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 150.

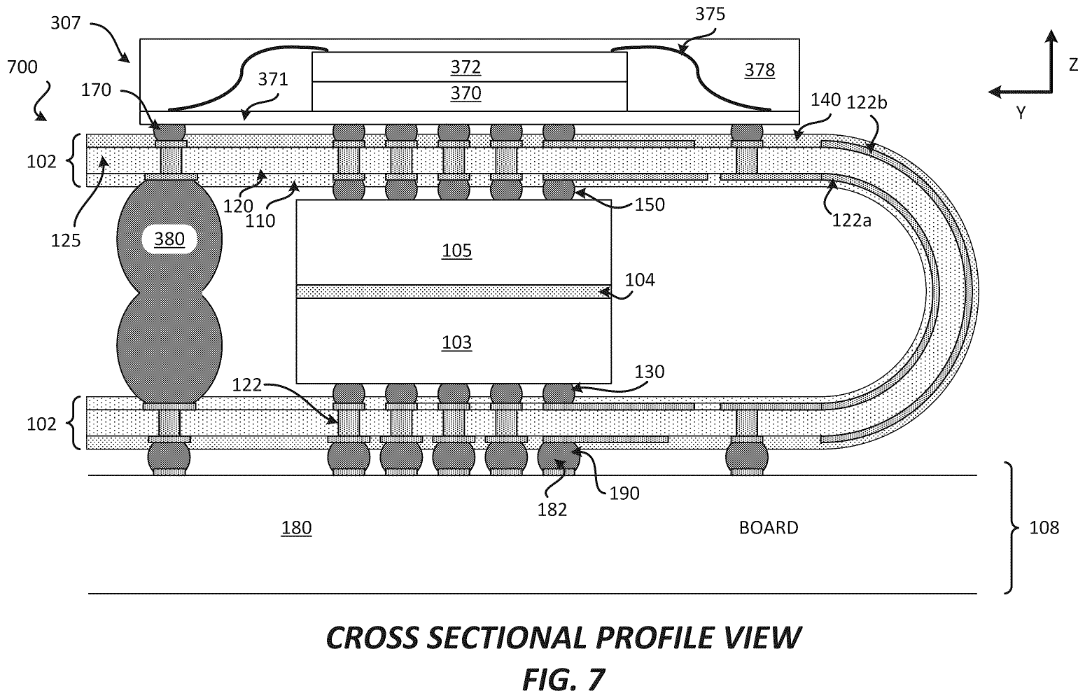

FIG. 7 illustrates the package 700 that includes a flexible substrate. The package 700 is similar to the package 300 and/or the package 600, and thus includes the same or similar components that are arranged in a similar manner as the package 300 and/or the package 600.

The integrated device 103 is configured to be electrically coupled to the integrated device 105 and/or the package 307 through the substrate 102. For example, an electrical path between the integrated device 103 and the integrated device 105 may include at least one solder interconnect from the plurality of solder interconnects 130, at least one interconnect from the plurality of interconnects 122 and at least one solder interconnect from the plurality of solder interconnects 150. An electrical path between the integrated device 103 and the integrated device 105 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 150.

An electrical path between the integrated device 103 and the package 307 may include at least one solder interconnect from the plurality of solder interconnects 130, at least one interconnect from the plurality of interconnects 122 and at least one solder interconnect from the plurality of solder interconnects 170. An electrical path between the integrated device 103 and the package 307 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 170.

An electrical path between the integrated device 105 and the package 307 may include at least one solder interconnect from the plurality of solder interconnects 150, at least one interconnect from the plurality of interconnects 122 and at least one solder interconnect from the plurality of solder interconnects 170.

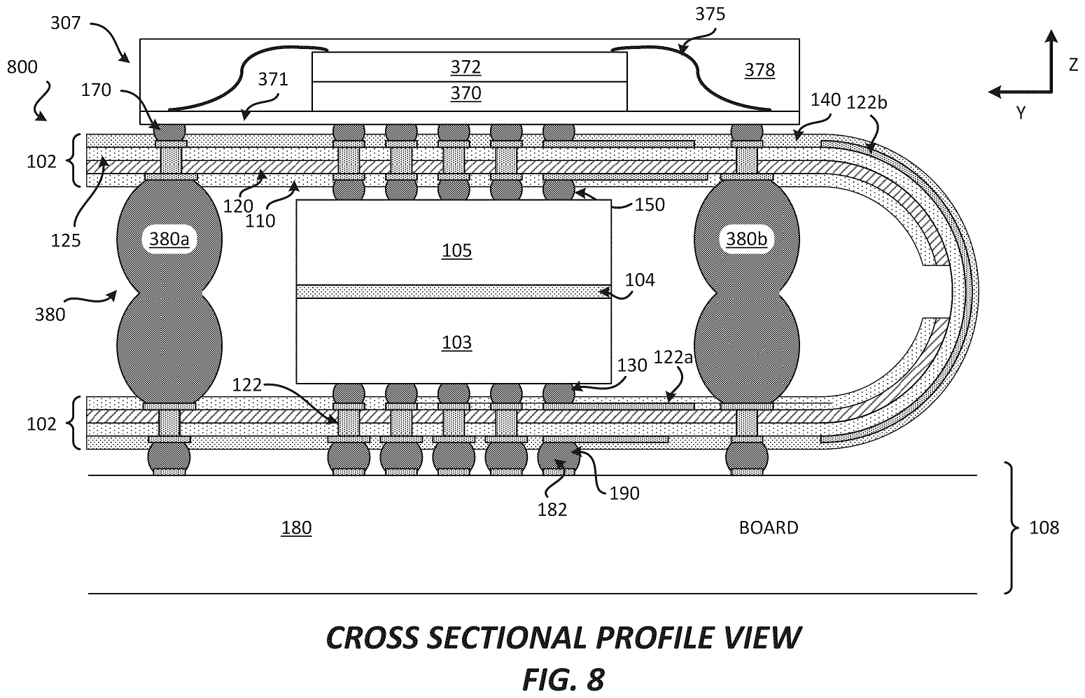

FIG. 8 illustrates the package 800 that includes a flexible substrate. The package 800 is similar to the package 400, and thus includes the same or similar components that are arranged in a similar manner as the package 400. The package 800 includes the substrate 102, an integrated device 103, an integrated device 105, the package 307 and a plurality of solder interconnects 380. FIG. 8 illustrates that a portion of the substrate 102 has been removed to help with the bending of the flexible portion of the substrate 102. For example, portions of the dielectric layer 110 and/or the dielectric layer 120 may have been removed in the flexible portion of the substrate 102.

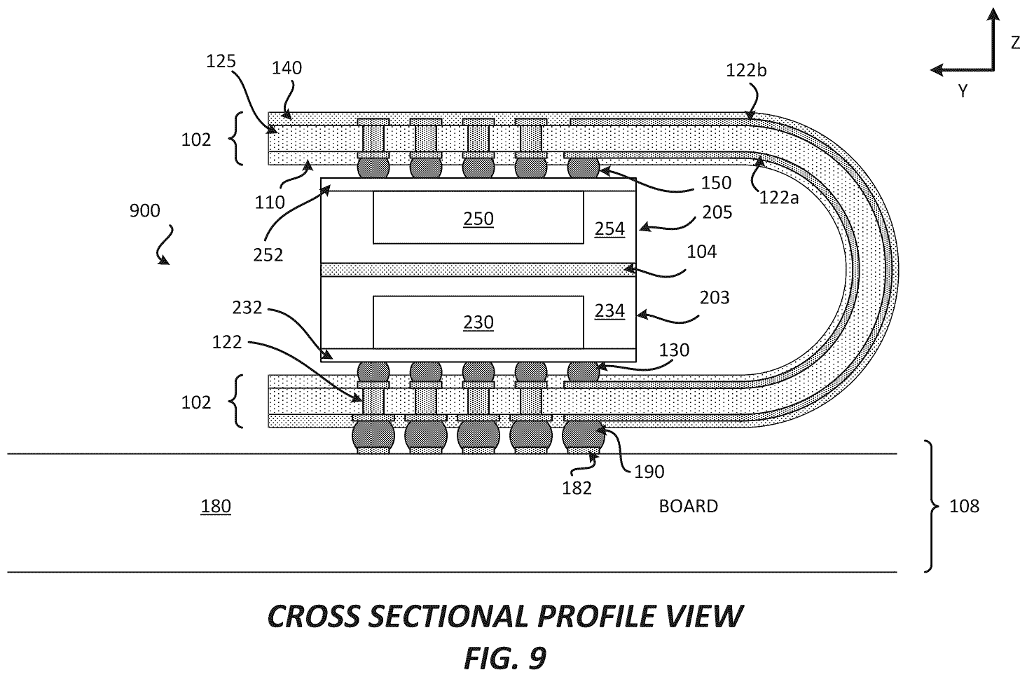

FIG. 9 illustrates the package 900 that includes a flexible substrate. The package 900 is similar to the package 500, and thus includes the same or similar components that are arranged in a similar manner as the package 500. The package 900 includes the substrate 102, an integrated device 203, an integrated device 205.

The integrated device 203 is configured to be electrically coupled to the integrated device 205 through the substrate 102. For example, an electrical path between the integrated device 203 and the integrated device 205 may include at least one solder interconnect from the plurality of solder interconnects 130, at least one interconnect from the plurality of interconnects 122 and at least one solder interconnect from the plurality of solder interconnects 150.

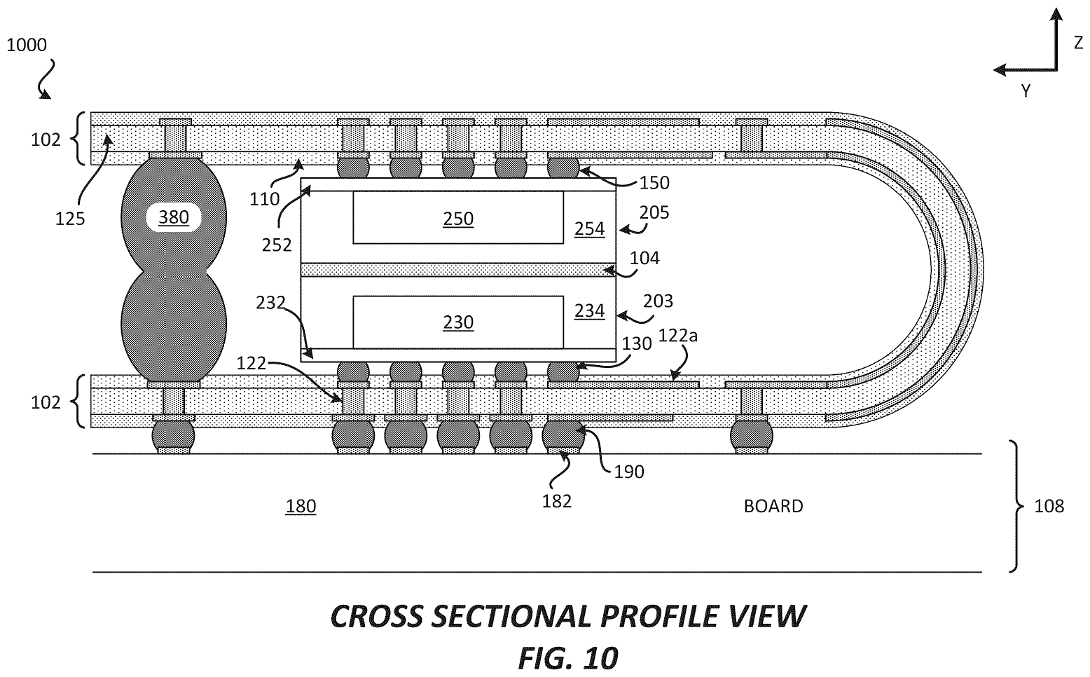

FIG. 10 illustrates the package 1000 that includes a flexible substrate. The package 1000 is similar to the package 800 and the package 900, and thus includes the same or similar components that are arranged in a similar manner as the package 800 and the package 900. The package 1000 includes the substrate 102, an integrated device 203, an integrated device 205 and a plurality of solder interconnects 380.

The integrated device 203 is configured to be electrically coupled to the integrated device 205 through the substrate 102. For example, an electrical path between the integrated device 203 and the integrated device 205 may include at least one solder interconnect from the plurality of solder interconnects 130, at least one interconnect from the plurality of interconnects 122 and at least one solder interconnect from the plurality of solder interconnects 150. An electrical path between the integrated device 203 and the integrated device 205 may include at least one solder interconnect from the plurality of solder interconnects 130, at least one interconnect from the plurality of interconnects 122, at least one solder interconnect from the plurality of solder interconnects 380, at least one interconnect from the plurality of interconnects 122 and at least one solder interconnect from the plurality of solder interconnects 150.

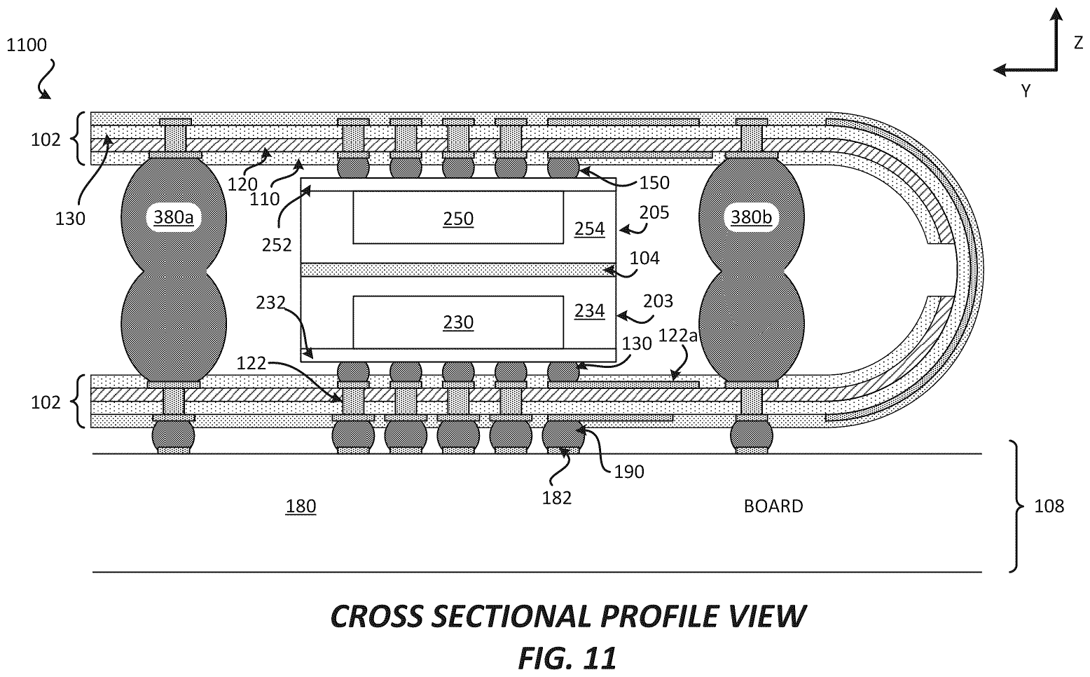

FIG. 11 illustrates the package 1100 that includes a flexible substrate. The package 1100 is similar to the package 1000, and thus includes the same or similar components that are arranged in a similar manner as the package 1000. The package 1000 includes the substrate 102, an integrated device 203, an integrated device 205 and a plurality of solder interconnects 380. FIG. 11 illustrates that a portion of the substrate 102 has been removed to help with the bending of the flexible portion of the substrate 102. For example, portions of the dielectric layer 110 and/or the dielectric layer 120 may have been removed in the flexible portion of the substrate 102.

It is noted that other implementations may use any combinations of the configuration shown in FIGS. 1-11.

FIG. 12 illustrates a plan view of package 1200 that includes a substrate 102, a plurality of interconnects 1222, a plurality of interconnects 1224, a plurality of interconnects 1226, an integrated device 1203 and an integrated device 1205. The substrate 102 includes a flexible portion. The substrate 102 shown in FIG. 12 is in an unfolded position. The plurality of interconnects 1222, the plurality of interconnects 1224 and the plurality of interconnects 1226 may represent the plurality of interconnects 122. The integrated device 1203 may represent the integrated device 103 or the integrated device 203. The integrated device 1205 may represent the integrated device 105 or the integrated device 205. In some implementations, the integrated device 1203 may be configured to be electrically coupled to the integrated device 1205 through the plurality of interconnects 1222. In some implementations, a plurality of solder interconnects 380 (not shown in FIG. 12) may be used to couple to the plurality of interconnects 1224 and the plurality of interconnects 1226, when the substrate 102 is bent. In some implementations, the integrated device 1203 may be configured to be electrically coupled to the integrated device 1205 through at least the plurality of interconnects 1224, the plurality of solder interconnects 380 and the plurality of interconnects 1226.

FIG. 12 may illustrate a fast surface of the substrate 102 that includes a first portion 1230 and a second portion 1250. FIG. 12 illustrates the integrated device 1203 is coupled to the first portion 1230 of the first surface of the substrate 102, and the integrated device 1205 is coupled to the second portion 1250 of the first surface of the substrate 102. The plurality of interconnects 1224 may be located in the first portion 1230 of the substrate 102 (e.g., located in the first portion 1230 of the first surface of the substrate 102). The plurality of interconnects 1226 may be located in the second portion 1250 of the substrate 102 (e.g., located in the second portion 1250 of the fast surface of the substrate 102). When the substrate 102 is folded, the first portion 1230 of the first surface of the substrate 102 may face towards the second portion 1250 of the first surface of the substrate 102. A plurality of solder interconnects 380 may be coupled to the first portion 1230 of the first surface of the substrate 102 and to the second portion 1250 of the first surface of the substrate 102. For example, the plurality of solder interconnects 380 may be coupled to the plurality of interconnects 1224 and the plurality of interconnects 1226. In some implementations, the first portion 1230 of the first surface of the substrate 102 may correspond to a first portion of the dielectric layer 110 of the substrate. In some implementations, the second portion 1250 of the first surface of the substrate 102 may correspond to a second portion of the dielectric layer 110 of the substrate.

An integrated device (e.g., 103, 105, 107) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 103, 105, 107) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Thus, for example, a single integrated device may be split into several chiplets. As mentioned above, using several chiplets that perform several functions may reduce the overall cost of a package relative to using a single chip to perform all of the functions of a package. In some implementations, one or more of the chiplets and/or one of more of integrated devices (e.g., 103, 105, 107) described in the disclosure may be fabricated using the same technology node or two or more different technology nodes. For example, an integrated device (e.g., 105) may be fabricated using a first technology node, and a chiplet (e.g., 103) may be fabricated using a second technology node that is not as advanced as the first technology node. In such an example, the integrated device (e.g., 107) may include components (e.g., interconnects, transistors) that have a first minimum size, and the chiplet (e.g., 103) may include components (e.g., interconnects, transistors) that have a second minimum size, where the second minimum size is greater than the first minimum size. In some implementations, the integrated device 107 and the integrated device 109 of a package, may be fabricated using the same technology node or different technology nodes. In some implementations, a chiplet (e.g., 103) and another chiplet (e.g., 105) of a package, may be fabricated using the same technology node or different technology nodes.

### Exemplary Sequence for Fabricating a Package Comprising a Flexible Substrate

In some implementations, fabricating a package includes several processes. FIG. 13A-13B illustrate an exemplary sequence for providing or fabricating a package comprising a flexible substrate. In some implementations, the sequence of FIGS. 13A-13B may be used to provide or fabricate the package 400 of FIG. 4 described in the disclosure. However, the sequence may be used to provide or fabricate any of the packages (e.g., 100, 200, 300, 500, 600, 700, 800, 900, 1000, 1100) described in the disclosure.

It should be noted that the sequence of FIGS. 13A-13B may combine one or more processes in order to simplify and/or clarify the method for providing or fabricating a package. In some implementations, the order of the processes may be changed or modified.

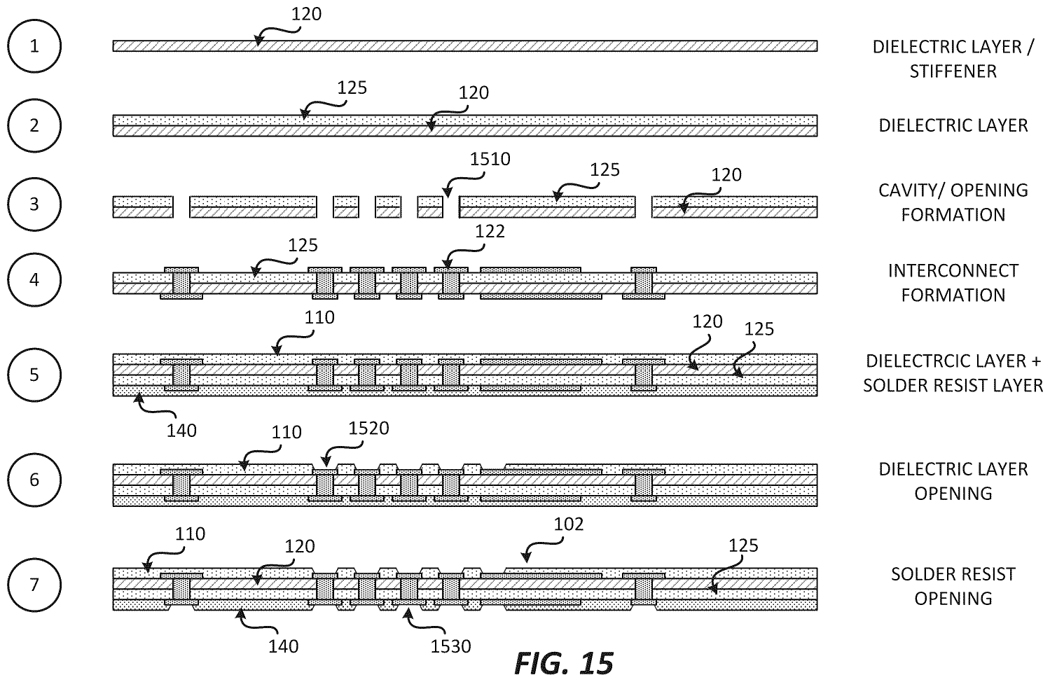

Stage 1 of FIG. 13A, illustrates a state after a substrate 102 is fabricated or provided. The substrate 102 includes a dielectric layer 110, a dielectric layer 120, a dielectric layer 125, a solder resist layer 140, and a plurality of interconnects 122. The substrate 102 may be fabricated using the sequence shown in FIG. 15. Stage 1 illustrates an example of the first portion 1230 of the substrate 102 and an example of the second portion 1250 of the substrate 102. It is noted that different implementations may define the first portion and the second of a substrate and/or the first portion and the second portion of a first surface of the a substrate differently. The first portion 1230 may include a first portion of a first surface of the substrate and/or a first portion of a second surface of the substrate. The second portion 1250 may include a second portion of a first surface of the substrate and/or a second portion of a second surface of the substrate. The designation of the first surface of the substrate 102 and the second surface of the substrate 102 is exemplary. In some implementations, the first surface and the second surface shown in Stage 1 of FIG. 13A may be switched. In some implementations, the first surface of the substrate 102 may include the dielectric layer 110 and the second surface of the substrate 102 may include the solder resist layer 140, as described above in at least FIGS. 1-11.

Stage 2, illustrates a state after portions of the dielectric layer 110 and portions of the dielectric layer 120 are removed. The portions of the dielectric layer 110 and/or portions of the dielectric layer 120 are removed to help provide a substrate with a flexible portion. A laser process and/or a photolithography process may be used to remove portions of the dielectric layer 110 and the dielectric layer 120.

Stage 3 illustrates a state after the integrated device 203 and the integrated device 205 are coupled to the first surface of the substrate 102. The integrated device 203 may be coupled to a first portion of the first surface of the substrate 102 through a plurality of solder interconnects 130. The integrated device 205 may be coupled to a second portion of the first surface of the substrate 102 through a plurality of solder interconnects 150. A solder reflow process may be used to couple the integrated device 203 and/or the integrated device 205 to the substrate 102.

Stage 4 illustrates a state after a plurality of solder interconnects 1380 are coupled to a first surface of the substrate 102. A solder reflow process may be used to couple the plurality of solder interconnects 1380 to the substrate 102. The plurality of solder interconnects 1380 may include a first plurality of solder interconnects 1380a, a second plurality of solder interconnects 1380h, a third plurality of solder interconnects 1380c, and a fourth plurality of solder interconnects 1380d.

Stage 5, as shown in FIG. 13B, illustrates a state after the substrate 102 is folded and a back side of the integrated device 203 is coupled to a back side of the integrated device 205. The first plurality of solder interconnects 1380a are coupled to the fourth plurality of solder interconnects 1380d to form the first plurality of solder interconnects 380a. The second plurality of solder interconnects 1380b are coupled to the third plurality of solder interconnects 1380c to form the second plurality of solder interconnects 380b.

Stage 6 illustrates a state after the package 307 is coupled to the substrate 102 through a plurality of solder interconnects 170. A solder reflow process may be used to couple the package 307 to the substrate 102. Stage 6 may illustrate the package 400 that includes the substrate 102, the integrated device 203, the integrated device 205, the package 307 and the plurality of solder interconnects 380.

It is noted that the above sequence may be modified such that the integrated device 203, the integrated device 205, and the plurality of solder interconnects 1380 are coupled to a second surface of the substrate 102, and the package 307 is coupled to the first surface of the substrate of the substrate 102.

### Exemplary Flow Diagram of a Method for Fabricating a Package Comprising a Flexible Substrate

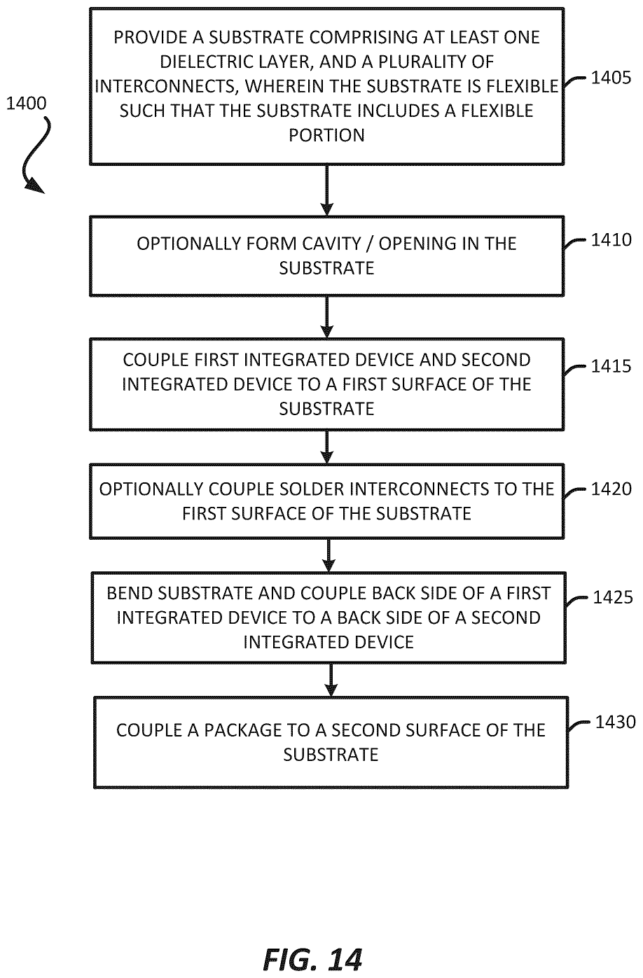

In some implementations, fabricating a package includes several processes. FIG. 14 illustrates an exemplary flow diagram of a method 1400 for providing or fabricating a package comprising a flexible substrate. In some implementations, the method 1400 of FIG. 14 may be used to provide or fabricate the package 400 of FIG. 4 described in the disclosure. However, the method 1400 may be used to provide or fabricate any of the packages (e.g., 100, 200, 300, 500, 600, 700, 800, 900, 1000, 1100) described in the disclosure.

It should be noted that the method of FIG. 14 may combine one or more processes in order to simplify and/or clarify the method for providing or fabricating a package. In some implementations, the order of the processes may be changed or modified.

The method provides (at 1405) a flexible substrate that includes at least one dielectric layer, a plurality of interconnects. Stage 1 of FIG. 13A, illustrates an example of a state after a substrate 102 is fabricated or provided. The substrate 102 includes a dielectric layer 110, a dielectric layer 120, a dielectric layer 125, a solder resist layer 140, and a plurality of interconnects 122. The substrate 102 may be fabricated using the sequence shown in FIG. 15.

The method optionally forms (at 1410) one or more openings in the substrate. Forming an opening may include removing portions of the substrate. Forming an opening and/or removing portions of the substrate may help the substrate to be flexible or more flexible. Stage 2 of FIG. 13A, illustrates an example of a state after portions of the dielectric layer 110 and portions of the dielectric layer 120 are removed. The portions of the dielectric layer 110 and/or portions of the dielectric layer 120 are removed to help provide a substrate with a flexible portion. A laser process and/or a lithography process may be used to remove portions of the dielectric layer 110 and the dielectric layer 120.

The method couples (at 1415) a first integrated device and a second integrated device to a first surface of the substrate. Stage 3 of FIG. 13A, illustrates an example of a state after the integrated device 203 (e.g., first integrated device) and the integrated device 205 (e.g., second integrated device) are coupled to the first surface of the substrate 102. The integrated device 203 may be coupled to a first portion of the first surface of the substrate 102 through a plurality of solder interconnects 130. The integrated device 205 may be coupled to a second portion of the first surface of the substrate 102 through a plurality of solder interconnects 150. A solder reflow process may be used to couple the integrated device 203 and/or the integrated device 205 to the substrate 102.

The method may optionally couples (at 1420) a plurality of solder interconnects to the substrate. Stage 4 of FIG. 13A, illustrates an example of a state after a plurality of solder interconnects 1380 are coupled to a first surface of the substrate 102. A solder reflow process may be used to couple the plurality of solder interconnects 1380 to the substrate 102. The plurality of solder interconnects 1380 may include a first plurality of solder interconnects 1380a, a second plurality of solder interconnects 1380b, a third plurality of solder interconnects 1380c, and a fourth plurality of solder interconnects 1380d.

The method bends (at 1425) the substrate and couple a back side of the integrated device to a back side of another integrated device. Stage 5 of FIG. 13B, illustrates an example of a state after the substrate 102 is folded and/or bonded and a back side of the integrated device 203 is coupled to a back side of the integrated device 205. The first plurality of solder interconnects 1380a are coupled to the fourth plurality of solder interconnects 1380d to form the first plurality of solder interconnects 380a. The second plurality of solder interconnects 1380b are coupled to the third plurality of solder interconnects 1380c to form the second plurality of solder interconnects 380b.

The method couple (at 1430) a package to a second surface of the substrate 102. Stage 6 of FIG. 13B, illustrates an example of a state after the package 307 is coupled to the substrate 102 through a plurality of solder interconnects 170. A solder reflow process may be used to couple the package 307 to the substrate 102. Stage 6 may illustrate the package 400 that includes the substrate 102, the integrated device 203, the integrated device 205, the package 307 and the plurality of solder interconnects 380.

### Exemplary Sequence for Fabricating a Flexible Substrate

In some implementations, fabricating a substrate includes several processes. FIG. 15 illustrates an exemplary sequence for providing or fabricating a flexible substrate. In some implementations, the sequence of FIG. 15 may be used to provide or fabricate the substrate 102. However, the process of FIG. 15 may be used to fabricate any of the substrates described in the disclosure.

It should be noted that the sequence of FIG. 15 may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 15, illustrates a state after a dielectric layer 120 is provided and/or formed. The dielectric layer 120 may be formed over a carrier (not shown). A deposition and/or lamination process may be used to form the dielectric layer 120. The dielectric layer 120 may be a stiffener.

Stage 2 illustrates a state after the dielectric layer 125 is provided and/or formed. The dielectric layer 125 may be formed over the dielectric layer 120. The dielectric layer 125 may include prepreg. A deposition and/or lamination process may be used to form the dielectric layer 125.

Stage 3 illustrates a state after a plurality of cavities 1510 are formed in the dielectric layer 120 and the dielectric layer 125. The plurality of cavities 1510 may be formed using a photolithography process (e.g., exposure and development) or laser process.

Stage 4 illustrates a state after a plurality of interconnects 122 are formed in and over the dielectric layer 120 and/or the dielectric layer 125, including in and over the plurality of cavities 1510. For example, a via, pad and/or traces may be formed. A plating process may be used to form the interconnects.

Stage 5 illustrates a state after a dielectric layer 110 is formed over the dielectric layer 120, and a solder resist layer 140 is formed over the dielectric layer 125. A deposition and/or lamination process may be used to form the dielectric layer 110 and the solder resist layer 140.

Stage 6 illustrates a state after a plurality of openings 1520 are formed in the dielectric layer 110. The plurality of openings 1520 may be formed using a photolithography process (e.g., exposure and development) or laser process.

Stage 7 illustrates a state after a plurality of openings 1530 are formed in the solder resist layer 140. The plurality of openings 1530 may be formed using a photolithography process or laser process. Stage 7 may illustrate an example of a substrate 102.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

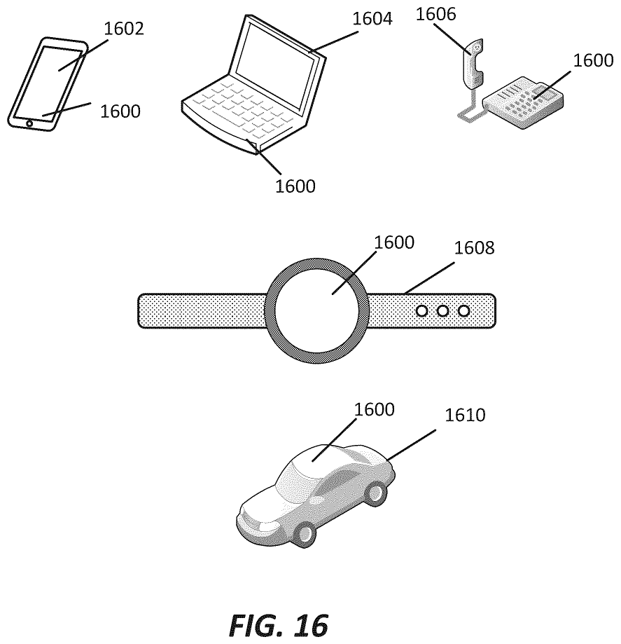

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (ToT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-12, 13A-13B and/or 14-16 may be rearranged and/or combined into a single component, process, feature or function or embodied in several components, processes, or functions. Additional elements, components, processes, and/or functions may also be added without departing from the disclosure. It should also be noted FIGS. 1-12, 13A-13B and/or 14-16 and its corresponding description in the present disclosure is not limited to dies and/or ICs. In some implementations, FIGS. 1-12, 13A-13B and/or 14-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B. and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “fast”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a fast component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a substrate, a first integrated device coupled to a first surface of the substrate, and a second integrated device coupled to the first surface of the substrate, where a back side of the second integrated device is coupled to a back side of the first integrated device through an adhesive. The substrate includes at least one dielectric layer; and a plurality of interconnects;

Aspect 2: The package of aspect 1, further comprising a plurality of solder interconnects, wherein the substrate comprises a first portion and a second portion, wherein the first portion faces the second portion, and wherein the plurality of solder interconnects is coupled to the first portion and the second portion.

Aspect 3: The package of aspects 1 through 2, wherein the substrate includes a flexible portion that is configured to bend such that the back side of the first integrated device faces the back side of the second integrated device in the package.

Aspect 4: The package of aspects 1 through 3, where the at least one dielectric layer includes a stiffener dielectric layer.

Aspect 5: The package of aspects 1 through 4, wherein the first integrated device comprises: a first metallization portion; a first semiconductor die; and a first encapsulation layer.

Aspect 6: The package of aspect 5, wherein the second integrated device comprises: a second metallization portion; a second semiconductor die; and a second encapsulation layer, wherein the second encapsulation layer of the second integrated device is coupled to the first encapsulation layer of the first integrated device through the adhesive.

Aspect 7: The package of aspects 1 through 6, further comprising a third integrated device coupled to a second surface of the substrate.

Aspect 8: The package of aspects 1 through 6, further comprising another package coupled to a second surface of the substrate.

Aspect 9: The package of aspects 1 through 8, wherein the substrate includes a flexible portion that includes an opening in the at least one dielectric layer.

Aspect 10: The package of aspects 1 through 9, wherein the second integrated device is located over the first integrated device such that the back side of the second integrated device faces the back side of the first integrated device.

Aspect 11: The package of aspects 1 through 10, wherein the first integrated device includes a first chiplet, and wherein the second integrated device includes a second chiplet.

Aspect 12: The package of aspects 1 through 11, further comprising a plurality of solder interconnects, wherein the substrate includes a flexible portion that is configured to bend such that the back side of the first integrated device faces the back side of the second integrated device in the package, wherein the substrate comprises a fast portion and a second portion, wherein the first portion faces the second portion, wherein the plurality of solder interconnects is coupled to the first portion and the second portion, wherein there are no solder interconnects between the first integrated device and the flexible portion of the substrate, and wherein there are no solder interconnects between the second integrated device and the flexible portion of the substrate.

Aspect 13: A device comprising a substrate, a first integrated device coupled to a first surface of the substrate and a second integrated device coupled to the first surface of the substrate, wherein a back side of the second integrated device is coupled to a back side of the first integrated device through an adhesive. The substrate includes at least one dielectric layer; and a plurality of interconnects.

Aspect 14: The device of aspect 13, further comprising a plurality of solder interconnects, wherein the substrate comprises a first portion and a second portion, wherein the first portion faces the second portion, and wherein the plurality of solder interconnects is coupled to the first portion and the second portion.

Aspect 15: The device of aspects 13 through 14, wherein the substrate includes a flexible portion that is configured to bend such that the back side of the first integrated device faces the back side of the second integrated device in the package.

Aspect 16: The device of aspects 13 through 15, where the at least one dielectric layer includes a stiffener dielectric layer.

Aspect 17: The device of aspects 13 through 16, wherein the first integrated device comprises a first metallization portion; a first semiconductor die; and a first encapsulation layer.

Aspect 18: The device of aspect 17, wherein the second integrated device comprises a second metallization portion; a second semiconductor die; and a second encapsulation layer, wherein the second encapsulation layer of the second integrated device is coupled to the first encapsulation layer of the first integrated device through the adhesive.

Aspect 19: The device of aspects 13 through 18, further comprising a third integrated device coupled to a second surface of the substrate.

Aspect 20: The device of aspects 13 through 18, wherein the substrate includes a flexible portion that includes an opening in the at least one dielectric layer.

Aspect 21: A method for fabricating a package. The method provides a substrate comprising at least one dielectric layer; and a plurality of interconnects. The method couples a first integrated device to a first surface of the substrate. The method couples a second integrated device to the first surface of the substrate. The method bends the substrate and coupling a back side of the second integrated device to a back side of the first integrated device through an adhesive.

Aspect 22: The method of aspect 21, further coupling a plurality of solder interconnects to a first portion and a second portion of the substrate, wherein bending the substrates causes the first portion to face the second portion.

Aspect 23: The method of aspects 21 through 22, wherein the substrate includes a flexible portion that is configured to bend such that the back side of the first integrated device faces the back side of the second integrated device in the package.

Aspect 24: The method of aspects 21 through 23, where the at least one dielectric layer includes a stiffener dielectric layer.

Aspect 25: The method of aspects 21 through 24, wherein the first integrated device comprises a first metallization portion, a first semiconductor die and a first encapsulation layer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate comprising:
at least one dielectric layer; and
a plurality of interconnects;
a first integrated device coupled to a first surface of the substrate; and
a second integrated device coupled to the first surface of the substrate, wherein a back side of the second integrated device is coupled to a back side of the first integrated device through an adhesive.

2. The package of claim 1, further comprising a plurality of solder interconnects,
wherein the substrate comprises a first portion and a second portion,
wherein the first portion faces the second portion, and
wherein the plurality of solder interconnects is coupled to the first portion and the second portion.

3. The package of claim 1, wherein the substrate includes a flexible portion that is configured to bend such that the back side of the first integrated device faces the back side of the second integrated device in the package.

4. The package of claim 1, where the at least one dielectric layer includes a stiffener dielectric layer.

5. The package of claim 1, wherein the first integrated device comprises:
a first metallization portion;
a first semiconductor die; and
a first encapsulation layer.

6. The package of claim 5,
wherein the second integrated device comprises:
a second metallization portion;
a second semiconductor die; and
a second encapsulation layer,
wherein the second encapsulation layer of the second integrated device is coupled to the first encapsulation layer of the first integrated device through the adhesive.

7. The package of claim 1, further comprising a third integrated device coupled to a second surface of the substrate.

8. The package of claim 1, further comprising another package coupled to a second surface of the substrate.

9. The package of claim 1, wherein the substrate includes a flexible portion that includes an opening in the at least one dielectric layer.

10. The package of claim 1, wherein the second integrated device is located over the first integrated device such that the back side of the second integrated device faces the back side of the first integrated device.

11. The package of claim 1,
wherein the first integrated device includes a first chiplet, and
wherein the second integrated device includes a second chiplet.

12. The package of claim 1, further comprising a plurality of solder interconnects,
wherein the substrate includes a flexible portion that is configured to bend such that the back side of the first integrated device faces the back side of the second integrated device in the package,
wherein the substrate comprises a first portion and a second portion,
wherein the first portion faces the second portion,
wherein the plurality of solder interconnects is coupled to the first portion and the second portion,
wherein there are no solder interconnects between the first integrated device and the flexible portion of the substrate, and
wherein there are no solder interconnects between the second integrated device and the flexible portion of the substrate.

13. A device comprising:
a substrate comprising:
at least one dielectric layer; and
a plurality of interconnects;
a first integrated device coupled to a first surface of the substrate; and
a second integrated device coupled to the first surface of the substrate, wherein a back side of the second integrated device is coupled to a back side of the first integrated device through an adhesive.

14. The device of claim 13, further comprising a plurality of solder interconnects,
wherein the substrate comprises a first portion and a second portion,
wherein the first portion faces the second portion, and
wherein the plurality of solder interconnects is coupled to the first portion and the second portion.

15. The device of claim 13, wherein the substrate includes a flexible portion that is configured to bend such that the back side of the first integrated device faces the back side of the second integrated device in the package.

16. The device of claim 13, where the at least one dielectric layer includes a stiffener dielectric layer.

17. The device of claim 13, wherein the first integrated device comprises:
a first metallization portion;
a first semiconductor die; and
a first encapsulation layer.

18. The device of claim 17,
wherein the second integrated device comprises:
a second metallization portion;
a second semiconductor die; and
a second encapsulation layer,
wherein the second encapsulation layer of the second integrated device is coupled to the first encapsulation layer of the first integrated device through the adhesive.

19. The device of claim 13, further comprising a third integrated device coupled to a second surface of the substrate.

20. The device of claim 13, wherein the substrate includes a flexible portion that includes an opening in the at least one dielectric layer.

21. A method for fabricating a package, comprising:
providing a substrate comprising:
at least one dielectric layer; and
a plurality of interconnects;
coupling a first integrated device to a first surface of the substrate;
coupling a second integrated device to the first surface of the substrate; and
bending the substrate and coupling a back side of the second integrated device to a hack side of the first integrated device through an adhesive.

22. The method of claim 21, further coupling a plurality of solder interconnects to a first portion and a second portion of the substrate, wherein bending the substrates causes the first portion to face the second portion.

23. The method of claim 21, wherein the substrate includes a flexible portion that is configured to bend such that the back side of the first integrated device faces the back side of the second integrated device in the package.

24. The method of claim 21, where the at least one dielectric layer includes a stiffener dielectric layer.

25. The method of claim 21, wherein the first integrated device comprises:
a first metallization portion;
a first semiconductor die; and
a first encapsulation layer.
